(19) United States
(12) Patent Application Publication
(10) Pub. No.: US 2008/0175152 A1
(43) Pub. Date: Jul. 24, 2008

(54) Service differentiating and overload indication for downlink

(75) Inventors: Daniela Laselva, Aalborg (DK); Troels E. Kolding, Klarup (DK); Jeroen Wigard, Klarup (DK)

Correspondence Address: HARRINGTON & SMITH, PC, 4 RESEARCH DRIVE, SHELTON, CT, 06484-6212, US

(73) Assignee: Nokia Corporation

(21) Appl. No.: 12/004,722

(22) Filed: Dec. 21, 2007

Related U.S. Application Data
(60) Provisional application No. 60/877,486, filed on Dec. 28, 2006.

(51) Int. Cl. G01R 31/08

(52) U.S. Cl. 370/235

(57) ABSTRACT

A method includes determining a discard packet ratio for one of a plurality of service groups associated with a cell of a wireless communication system; comparing the determined discard packet ratio to a threshold value; and if the threshold value is exceeded, performing at least one overload control action, such as reducing a bit rate or dropping (lower priority) user equipment. The exemplary embodiments provide in one aspect thereof a framework that includes a scheduling priority indicator-based QoS control measure that employs a discarded packets measure for estimating a QoS provision within each scheduling priority indicator group, and a scheduling priority indicator-based overload indication for deciding whether a particular scheduling priority indicator group has been provided with a required QoS.

### CLAIM OF PRIORITY FROM COPENDING PROVISIONAL PATENT APPLICATION

This patent application claims priority under 35 U.S.C. §119(e) from Provisional Patent Application No. 60/877,486, filed Dec. 28, 2006, the disclosure of which is incorporated by reference herein in its entirety.

### TECHNICAL FIELD

The exemplary and non-limiting embodiments of this invention relate generally to wireless communication systems, methods, devices and computer program products and, more specifically, relate to techniques for controlling downlink transmissions from a wireless network to at least one user equipment.

### BACKGROUND

Certain abbreviations that are found in the specification are defined as follows:

3GPP third generation partnership project
AC admission control
BR bit rate
DL downlink (Node B to UE)
E-UTRAN evolved universal terrestrial radio access network
GBR guaranteed bit rate
HSDPA high speed downlink packet access
HS-DSCH high-speed downlink shared channel
LC load control
LTE long term evolution
Node B base station
NRT non-real time
PS packet scheduler
RNC radio network controller.
RT real time
SPI scheduling priority indicator
QoS quality of service
UE user equipment
UL uplink (UE to Node B)
WCDMA wideband code division multiple access

In one conventional approach QoS control is performed at the cell base station. This approach implies that load control is based on cell-specific load measurements and on cell specific AC, PS and LC algorithms. In addition, cell-specific load thresholds are established by radio network planning. In the case of overload control, the only differentiation that is made within a cell is in terms of RT versus NRT traffic (e.g., the selection of the bearers, whose throughput need to be decreased, is done randomly among NRT traffic classes).

If the load in the cell exceeds the overload threshold (for UL and DL separately), the LC, AC and PS functions may perform some overload actions to decrease loading, such as by blocking call admission (AC) and decreasing the BR for NRT traffic (PS). The overload threshold can be based on feedback measurements that the RNC receives from the Node-B.

More specifically, the QoS control mechanisms on the radio interface are typically placed in the AC, LC and PS functions. The primary goal in this respect is to maintain the network load stable while providing the required QoS and, if needed, recovering from a network overload condition to a normal load state as quickly as possible. In the traditional approach the LC function updates the cell load status based on radio resource measurements and estimations. In the case of an overload some control actions are performed, such as the AC function blocking new calls, the PS function decreasing NRT bit rates in the cell, and/or the LC function dropping some existing calls.

Publications that may be of interest to this subject matter include “Overview of QoS Options for HSDPA”, Klaus I. Pedersen, Preben E. Mogensen, Troels E. Kolding, IEEE Communications Magazine, July 2006, pgs. 100-105; “Scheduling Algorithms For Policy Driven QoS Support in HSDPA Networks”, Gomes, J. S., Yun, M., Hyeong-Ah Choi, Jae-Hoon Kim, JungKyo Sohn, Hyeong In Choi, Vehicular Technology Conference, 2007, VTC2007-Spring. IEEE 65th, 22-25 Apr. 2007, pgs. 799-803; and US Patent Application Publication No.: 2007/0053288 A1, “Wireless Communication Method and Apparatus for Selecting a Channel Type for a Call”, J. Stern-Berkowitz et al.

### SUMMARY OF THE EXEMPLARY EMBODIMENTS

In accordance with a first aspect of the exemplary embodiments of this invention there is provided a method that comprises determining a discard packet ratio for one of a plurality of service groups associated with a cell of a wireless communication system; comparing the determined discard packet ratio to a threshold value; and if the threshold value is exceeded, performing at least one overload control action.

In accordance with another aspect of the exemplary embodiments of this invention there is provided a computer-readable memory medium that stores program instructions, the execution of which result in operations that comprise determining a discard packet ratio for one of a plurality of service groups associated with a cell of a wireless communication system; comparing the determined discard packet ratio to a threshold value, and if the threshold value is exceeded, performing at least one overload control action.

In accordance with another aspect of the exemplary embodiments of this invention there is provided an apparatus that includes an interface and a controller coupled with the interface and configurable to provide QoS provisioning within a cell of a wireless communication network. The controller is configured to determine a discard packet ratio for one of a plurality of service groups; to compare the determined discard packet ratio to a threshold value and to be responsive to a condition that the threshold value is exceeded, to perform at least one overload control action.

In accordance with another aspect of the exemplary embodiments of this invention there is provided an apparatus that includes means for determining a discard packet ratio for one of a plurality of service groups associated with a cell of a wireless communication system; means for comparing the determined discard packet ratio to a threshold value; and means, responsive to the threshold value being exceeded, for performing at least one overload control action. The means for determining the discard packet ratio, for comparing and for performing the at least one overload control action operate in an iterative fashion until the determined discard packet ratio is less than the threshold. The means for determining the discard packet ratio and for comparing operate on a plurality of service groups in turn, once per averaging period, beginning with a highest priority service group.

### BRIEF DESCRIPTION OF THE DRAWINGS

In the attached Drawing Figures:

FIG. 1 shows a simplified block diagram of a wireless network that includes various electronic devices that are suitable for use in practicing the exemplary embodiments of this invention.

FIG. 2 is another view of the network shown in FIG. 1, and is also useful in describing the exemplary embodiments of this invention.

FIG. 3 is a graph that depicts various packet discard thresholds, per SPI value.

FIG. 4 is a logic flow diagram that is descriptive of a method and a computer program product in accordance with the exemplary embodiments of this invention.

### DETAILED DESCRIPTION

As different services typically co-exist within the same cell, a differentiation between the services is desirable in order to take service-based actions in the case of an overload. Prior to this invention, this need was not adequately addressed.

In general, it is known the differentiation is desirable to achieve a better utilization of the resources. Also, some service based actions in load control are known. The presently preferred embodiments of this invention, however, provide novel criteria and a novel method to achieve differentiation between services, as will be described below in reference to, for example, FIG. 4.

The exemplary embodiments of this invention provide a service differentiating QoS (more specifically, load control, which includes QoS differentiation), and overload control in HSDPA, and provide a SPI-based overload indication to provide QoS to multiple services having differing QoS requirements in the DL. However, the exemplary embodiments of this invention are not limited for use in only HSDPA, and have applicability in other types of access systems and methodologies.

That is, it should be noted at the outset that while the exemplary embodiments of this invention are described in the context of 3GPP WCDMA/HSDPA, the use of these embodiments is not restricted to only this one particular type of wireless communication system. Instead, the exemplary embodiments of this invention may be adopted for providing, as non-limiting examples, QoS control and QoS differentiation in LTE (E-UTRAN).

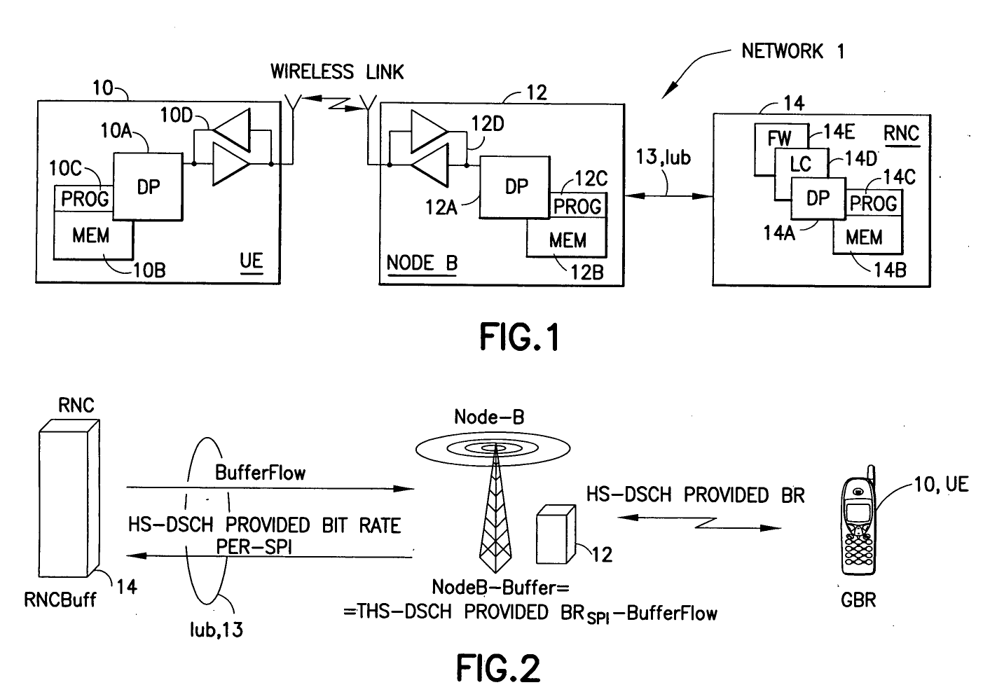

Reference is made first to FIG. 1 for illustrating a simplified block diagram of various electronic devices that are suitable for use in practicing the exemplary embodiments of this invention. In FIG. 1 a wireless network 1 is adapted for communication with a UE 10 via a Node B (base station) 12. The network 1 includes a network control element which may be embodied as an RNC 14. The UE 10 includes a data processor (DP) 10A, a memory (MEM) 10B that stores a program (PROG) 10C, and a suitable radio frequency (RF) transceiver 10D for bidirectional wireless communications with the Node B 12, which also includes a DP 12A, a MEM 12B that stores a PROG 12C, and a suitable RF transceiver 12D. The Node B 12 is coupled via a data path 13, such as an Iub interface, to the RNC 14 that also includes a DP 14A and a MEM 14B storing an associated PROG 14C. At least the PROG 14C is assumed to include program instructions that, when executed by the associated DP (computer), enable the electronic device to operate in accordance with the exemplary embodiments of this invention, as will be discussed below in greater detail.

Towards this end it is assumed that the RNC 14 includes a LC function or module or algorithm 14D.

That is, the exemplary embodiments of this invention may be implemented at least in part by computer software executable by at least one of the DPs, or by hardware, or by a combination of software and hardware.

In general, the various embodiments of the UE 10 can include, but are not limited to, cellular telephones, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions.

The MEMs 10B, 12B and 14B may be of any type suitable to the local technical environment and may be implemented using any suitable data storage technology, such as semiconductor-based memory devices, magnetic memory devices and systems, optical memory devices and systems, fixed memory and removable memory. The DPs 10A, 12A and 14A may be of any type suitable to the local technical environment, and may include one or more of general purpose computers, special purpose computers, microprocessors, digital signal processors (DSPs) and processors based on a multi-core processor architecture, as non-limiting examples.

The exemplary embodiments of this invention comprise a framework (FW) 14E that includes: (a) a SPI-based QoS control measure employing a discarded packets measure for estimating the QoS provision within each SPI group, and (b) a SPI-based overload indication for deciding whether an SPI group has been provided with the required QoS. The framework 14E may be incorporated with, or otherwise coupled to, the LC 14D in the RNC 14.

The use of the framework 14E resolves the questions as to whether the required QoS per each SPI is being provided, and which service priorities shall the actions to guarantee the required QoS, in the case of an overload, be targeted to?

To illustrate further, consider the system shown in FIG. 2. In respect to the disclosed framework 14E, the QoS interface in the Iub interface 13 for HSDPA includes the Node-B 12 feedback measurements sent to the RNC 14 every 100 ms (i.e., the HS-DSCH provided bit rate as average cell bit rate for all HSDPA-users with the same SPI value) and the required power to support the sum of GBRs per SPI class is sent to the Node-B 12.

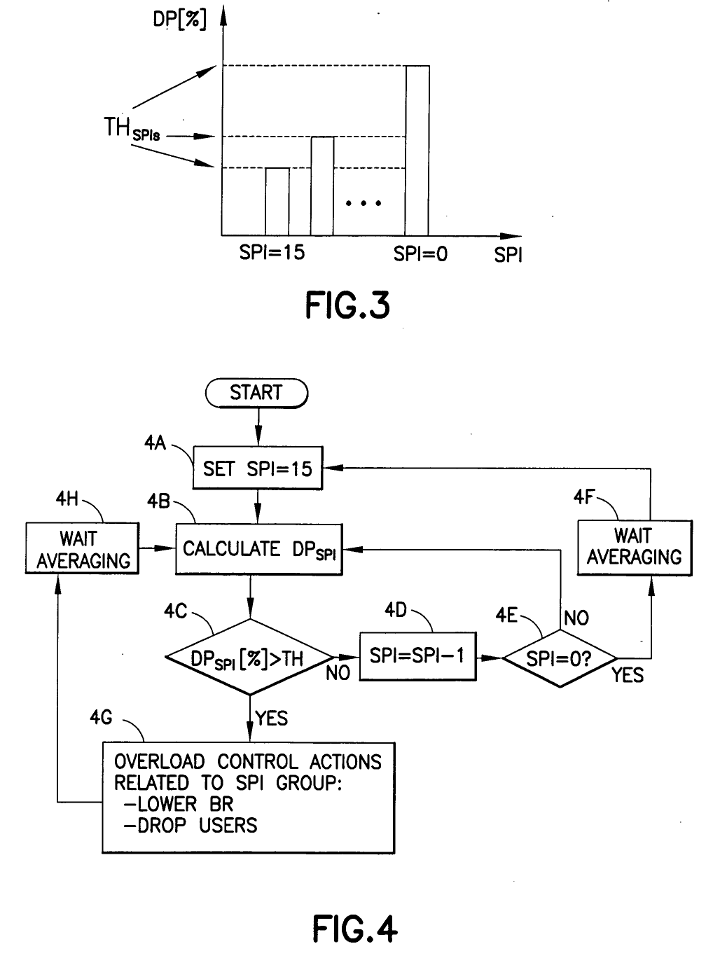

FIG. 3 shows the setting of a plurality of discard packet thresholds for each SPI value in the RNC 14, where it is assumed for convenience, but not as a limitation, that the setting is static: i.e., each SPI group shall be associated with a certain threshold based on the QoS requirements of the services mapped to that SPI value. However this can be generalized to the case where the thresholds are allocated dynamically depending on, for example, the load level, and may be used as a measure to share any excess capacity. The procedure is flexible, since all the SPI groups may be mapped to the same threshold to reduce the complexity of the framework 14E algorithm.

Note that data packets may be discarded due to a number of reasons, such as the overload of any radio resources and/or transport resources, or due to QoS issues (e.g., not fulfilling delay constraints in RT services).

It should be noted that an aspect of the exemplary embodiments of this invention is an ability to estimate in a network node, such as the RNC 14, the ratio of discarded packets in the Node-B 12. While several techniques to accomplish this estimation are possible, what follows is a description of one exemplary and non-limiting technique.

### EXAMPLE

### Prediction Based on Node-B Buffer Flow for each SPI Group

This prediction (estimation) algorithm is described in FIG. 4, which may be viewed as being illustrative of the algorithm for QoS control and triggering of overload actions, as well as the result of the execution of a computer program product. In FIG. 4 a comparison between the Discard Packets and the related Packet Discard threshold is used as trigger for service-based overload control. The algorithm is executed every averaging period, and the actual interval depends on the estimation of DP_{SPI}. For example, it may be performed every 100 ms or some multiple thereof, while in a BufferFlow-based approach the execution interval can depend on a discard timer.

Briefly, at Block 4A the SPI is initially set to the highest priority (e.g., 15), and at Block 4B the discard packet ratio DP_{SPI} for the current SPI group is calculated (see equation (1) below). At Block 4C the calculated DP_{SPI} is compared to a threshold (TH) value (which may be an SPI-dependent threshold, see FIG. 3). If the threshold is not exceeded, control passes to Block 4D to decrement the SPI value, and a comparison is made at Block 4E to determine if the SPI has reached some minimum value (SPI=0 in this example). If it has not control returns to Block 4B to calculate the DP_{SPI} for the current SPI group. If the minimum SPI value has been reached, then control passes instead Block 4F to delay for some period (Wait Averaging, e.g., 100 ms), after which control passes to Block 4A to reset the SPI to the maximum value and then re-enter the calculation/comparison loop. At Block 4C, and for the case where the calculated DP_{SPI} does exceed the threshold, control passes to Block 4G to perform at least one overload control action. Control then passes to a delay block 4H (Wait Averaging) after which the DP_{SPI} is again calculated for the same SPI value. Note that the loop comprised of Blocks 4B, 4C, 4G and 4H can be executed a plurality of times until the activity performed by Block 4G is successful in reducing the value of DP_{SPI}, for the current SPI value, below the SPI-specific threshold.

During each averaging period, the discard packet ratio, DP_{SPI}, as the QoS control measure may be calculated as follows during execution of the Block 4B:

$${DP}_{SPI} [ t ] = ( \frac{\begin{matrix}{\sum }_{k ∈ SPIgroup} {BufferFlow}_{k} ( t ) - \\ ( HS - DSCH {ProvidedBR}_{SPI} ( t ) )\end{matrix}}{{\sum }_{k ∈ SPIgroup} {BufferFlow}_{k} ( t )} ) * 100 [ \% ] \qquad Eq . ( 1 )$$

where BufferFlowₖ is the buffer flow to the Node-B 12 related to the user k within the averaging period t, and HS-DSCHProvidedBR_{SPI} is the average cell bit rate measurement for all HSDPA-users with the same SPI value. DP_{SPI} represents the percentage of packets which have been discarded in the previous averaging period per SPI group due to overload in the Iub or on the air interface. In order to account for the discarded packets, the averaging period t in the previous expression is made equal to or greater than a per-SPI discard timer, and rounded to the next measurement HS-DSCH provided bit rate measurement. Therefore, the averaging period is SPI-dependent. Load control actions may be based on observing a plurality of measuring periods.

The estimated DP_{SPI} (Block 4B) is compared against the Discard Packet Thresholds TH_{SPIs} (Block 4C) This comparison acts as an overload indication and can generate a trigger for the overload control actions performed in Block 4G. That is, for the case where more packets then are allowed within a certain SPI group were discarded, the overload mechanisms for QoS provisioning are applied. These overload mechanisms for QoS provisioning may include, as examples, one or more of lowering the BRs and dropping lower priority SPI groups starting from the lowest priority SPI group.

Note that in the case of the QoS not being guaranteed within some SPI group, it is not meaningful to check the QoS provision in the lower priority SPIs since the overload actions might be targeted to all or the same ones of the lower priority groups. The number of averaging periods needed to converge to a state of the desired QoS provisioning depends at least in part on the overload actions themselves.

There are a number of advantages that can be realized by the use of the exemplary embodiments of this invention. For example, the use of the exemplary embodiments of this invention accurately and instantaneously assesses the QoS provision, and enables QoS control to be performed per SPI, supporting the QoS provision in multiple services. Furthermore, the use of the exemplary embodiments of this invention is flexible and allows different degrees of complexity, and can be integrated readily with load control, admission control and packet scheduling activities.

It should be noted that while the exemplary embodiments have been described in the context of the RNC 14, the framework function may be implemented in the Node B 12, or more generally in a base station or base station subsystem, where in this case the discard packet ratio need not be estimated, but may be directly measured.

Based on the foregoing it should be apparent that the exemplary embodiments of this invention provide a method, apparatus and computer program product(s) to ensure desired QoS provisioning within a cell, comprising determining a discard packet ratio for one of a plurality of service groups; comparing the determined discard packet ratio to a threshold value; and if the threshold value is exceeded, performing at least one overload control action.

The method, apparatus and computer program product(s) of the previous paragraph, further comprising repeating the steps of determining the discard packet ratio, comparing and performing the at least one overload control action until the determined discard packet ratio is less than the threshold.

The method, apparatus and computer program product(s) of the previous paragraphs, where the steps of determining the discard packet ratio and comparing are performed for a plurality of service groups in turn, beginning with a highest priority service group, and are repeated once per averaging period.

The method, apparatus and computer program product(s) of the previous paragraphs, where the threshold is a SPI-specific threshold.

The method, apparatus and computer program product(s) of the previous paragraphs, where the threshold is one of static or dynamic.

The method, apparatus and computer program product(s) of the previous paragraphs, where the at least one overload control action comprises reducing a bit rate.

The method, apparatus and computer program product(s) of the previous paragraphs, where the at least one overload control action comprises dropping at least one user.

The method, apparatus and computer program product(s) of the previous paragraph, where the dropped user is associated with a lower priority service group.

The method, apparatus and computer program product(s) of the previous paragraphs, executed and/or implemented in a radio network controller.

The method, apparatus and computer program product(s) of the previous paragraphs, where determining a discard packet ratio for one of a plurality of service groups is accomplished using Equation (1).

Also disclosed herein is an apparatus and a device to provide a desired QoS provisioning within a cell, and comprising means for determining a discard packet ratio for one of a plurality of service groups; means for comparing the determined discard packet ratio to a threshold value; and means, responsive to a condition that the threshold value is exceeded, for performing at least one overload control action.

The device of the previous paragraph, embodied in a radio network controller, and where said means for determining comprises means for estimating the discard packet ratio.

The device of the paragraph that precedes the previous paragraph, embodied in a base station, and where said means for determining comprises means for directly measuring the discard packet ratio.

Note that the various blocks shown in FIG. 4 may be viewed as method steps, and/or as operations that result from operation of computer program code, and/or as a plurality of coupled logic circuit elements constructed to carry out the associated function(s).

In general, the various exemplary embodiments may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the exemplary embodiments of this invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

As such, it should be appreciated that at least some aspects of the exemplary embodiments of the inventions may be practiced in various components such as integrated circuit chips and modules. The design of integrated circuits is by and large a highly automated process. Complex and powerful software tools are available for converting a logic level design into a semiconductor circuit design ready to be fabricated on a semiconductor substrate. Such software tools can automatically route conductors and locate components on a semiconductor substrate using well established rules of design, as well as libraries of pre-stored design modules. Once the design for a semiconductor circuit has been completed, the resultant design, in a standardized electronic format (e.g., Opus, GDSII, or the like) may be transmitted to a semiconductor fabrication facility for fabrication as one or more integrated circuit devices.

It should be noted that the terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements can be physical, logical, or a combination thereof. As employed herein two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Various modifications and adaptations to the foregoing exemplary embodiments of this invention may become apparent to those skilled in the relevant arts in view of the foregoing description, when read in conjunction with the accompanying drawings. For example, and as was noted above, the discard packet thresholds may be one of static or dynamic in nature. Further by example, and as was also noted above, the exemplary embodiments of this invention are not intended to be limited to any one type of wireless technology or access technique. Further, it should be noted that the wait averaging periods shown in Blocks 4F and 4H of FIG. 4 may be the same, e.g., 100 ms, or they may be different. Further, the Equation (1) above is meant to be exemplary of one suitable procedure for determining the discard packet ratio, and is not intended to be construed in a limiting sense upon the implementation and practice of the exemplary embodiments. Thus, any and all modifications to the disclosed embodiments will still fall within the scope of the non-limiting and exemplary embodiments of this invention.

Furthermore, some of the features of the various non-limiting and exemplary embodiments of this invention may be used to advantage without the corresponding use of other features. As such, the foregoing description should be considered as merely illustrative of the principles, teachings and exemplary embodiments of this invention, and not in limitation thereof.

What is claimed is:

1. A method, comprising:
determining a discard packet ratio for one of a plurality of service groups associated with a cell of a wireless communication system;
comparing the determined discard packet ratio to a threshold value; and
if the threshold value is exceeded, performing at least one overload control action.

2. The method of claim 1, further comprising repeating the steps of determining the discard packet ratio, comparing and performing the at least one overload control action until the determined discard packet ratio is less than the threshold.

3. The method of claim 1, where the steps of determining the discard packet ratio and comparing are performed for a plurality of service groups in turn, beginning with a highest priority service group, and are repeated once per averaging period.

4. The method of claim 1, where the threshold is a scheduling priority indicator specific threshold.

5. The method of claim 1, where the threshold is one of static or dynamic.

6. The method of claim 1, where the at least one overload control action comprises reducing a bit rate.

7. The method of claim 1, where the at least one overload control action comprises dropping at least one user equipment.

8. The method of claim 7, where the dropped user equipment is associated with a lower priority service group.

9. The method of claim 1, executed in a radio network controller, where in the radio network controller determining the discard packet ratio comprises estimating the discard packet ratio.

10. The method of claim 1, executed in a base station, where in the base station determining the discard packet ratio comprises measuring the discard packet ratio

11. The method of claim 1, where determining the discard packet ratio DP_{SPI} for one of a plurality of service groups is accomplished in accordance with:
$${DP}_{SPI} [ t ] = ( \frac{\begin{matrix}{\sum }_{k ∈ SPIgroup} {BufferFlow}_{k} ( t ) - \\ ( HS - DSCH {ProvidedBR}_{SPI} ( t ) )\end{matrix}}{{\sum }_{k ∈ SPIgroup} {BufferFlow}_{k} ( t )} ) * 100 [ \% ]$$
where BufferFlowₖ is a buffer flow to a Node-B related to user k within an averaging period t, and HS-DSCHProvidedBR_{SPI} is an average cell bit rate measurement for all users with the same SPI value.

12. The method of claim 11, where DP_{SPI} represents a percentage of packets that have been discarded in a previous averaging period per SPI group.

13. The method of claim 12, further comprising accounting for the discarded packets by making the averaging period t equal to or greater than a per-scheduling priority indicator discard timer, and rounded to a next measurement bit rate measurement.

14. A computer-readable memory medium that stores program instructions, the execution of which result in operations that comprise:
determining a discard packet ratio for one of a plurality of service groups associated with a cell of a wireless communication system;
comparing the determined discard packet ratio to a threshold value; and
if the threshold value is exceeded, performing at least one overload control action.

15. The computer-readable memory medium of claim 14, further comprising operations of repeating the operations of determining the discard packet ratio, comparing and performing the at least one overload control action until the determined discard packet ratio is less than the threshold, and where the operations of determining the discard packet ratio and comparing are performed for a plurality of service groups in turn, beginning with a highest priority service group, and are repeated once per averaging period.

16. The computer-readable memory medium of claim 14, where the threshold is a scheduling priority indicator specific threshold and is one of static or dynamic.

17. The computer-readable memory medium of claim 14, where the at least one overload control action comprises at least one of reducing a bit rate and dropping at least one user equipment associated with a lower priority service group.

18. The computer-readable memory medium of claim 14, embodied in one of a radio network controller and a base station, where in the radio network controller the operation of determining the discard packet ratio comprises estimating the discard packet ratio, and where in the base station determining the discard packet ratio comprises an operation of measuring the discard packet ratio.

19. The computer-readable memory medium of claim 14, where the operation of determining the discard packet ratio DP_{SPI} for one of a plurality of service groups is accomplished in accordance with:
$${DP}_{SPI} [ t ] = ( \frac{\begin{matrix}{\sum }_{k ∈ SPIgroup} {BufferFlow}_{k} ( t ) - \\ ( HS - DSCH {ProvidedBR}_{SPI} ( t ) )\end{matrix}}{{\sum }_{k ∈ SPIgroup} {BufferFlow}_{k} ( t )} ) * 100 [ \% ]$$
where BufferFlowₖ is a buffer flow to a Node-B related to user k within an averaging period t, and HS-DSCHProvidedBR_{SPI} is an average cell bit rate measurement for all users with the same SPI value.

21. The computer-readable memory medium of claim 14, where DP_{SPI} represents a percentage of packets that have been discarded in a previous averaging period per SPI group, and further comprising accounting for the discarded packets by making the averaging period t equal to or greater than a per-scheduling priority indicator discard timer, and rounded to a next measurement bit rate measurement.

22. An apparatus, comprising:
an interface; and
a controller coupled with said interface and configurable to provide QoS provisioning within a cell of a wireless communication network, said controller configured to determine a discard packet ratio for one of a plurality of service groups; to compare the determined discard packet ratio to a threshold value and to be responsive to a condition that the threshold value is exceeded, to perform at least one overload control action.

23. The apparatus of claim 22, embodied in a radio network controller where said controller estimates the discard packet ratio, or embodied in a base station where said controller measures the discard packet ratio.

24. An apparatus, comprising:
means for determining a discard packet ratio for one of a plurality of service groups associated with a cell of a wireless communication system;
means for comparing the determined discard packet ratio to a threshold value; and
means, responsive to the threshold value being exceeded, for performing at least one overload control action;
said means for determining the discard packet ratio, comparing and performing the at least one overload control action operating in an iterative fashion until the determined discard packet ratio is less than the threshold;
and where said means for determining the discard packet ratio and comparing operate on a plurality of service groups in turn, once per averaging period, beginning with a highest priority service group.

25. The apparatus of claim 24, embodied in a radio network control node wherein said determining means estimates the discard packet ratio, or embodied in a base station wherein said determining means measures the discard packet ratio.
